(19) United States
(12) Patent Application Publication
(10) Pub. No.: US 2025/0182926 A1
(43) Pub. Date: Jun. 5, 2025

(54) CONNECTION CONDUCTOR, ARRANGEMENT HAVING A CONNECTION CONDUCTOR AND USE OF A CONNECTION CONDUCTOR

(71) Applicant: Siemens Aktiengesellschaft, München (DE)

(72) Inventors: Jörg Braune, Berlin (DE); Dimitrij Klingbeil, Berlin (DE); Philipp Schuhmann, Berlin (DE); Alexander Jabs, Hennigsdorf (DE)

(21) Appl. No.: 18/964,912

(22) Filed: Dec. 2, 2024

(30) Foreign Application Priority Data
Nov. 30, 2023 (EP) 23213236.5

(51) Int. Cl. H01B 7/00; H01B 7/02; H01B 7/26

(52) U.S. Cl. CPC H01B 7/0054; H01B 7/02; H01B 7/26

(57) ABSTRACT

A connection conductor electrically connects a sensor, the output side of which provides measurement signals, to an intelligent electronic device which is set up to process the measurement signals. The connection conductor has conductor phases arranged insulated from one another, a sensor end on which is formed a conductor input for electrically connecting to an output of the sensor, and an evaluation-unit end which has a conductor output for electrically connecting to an input of the evaluation unit. The two conductor phases extend from the conductor input to the conductor output and are set up to transmit the measurement signals between the output of the sensor and the input of the evaluation unit. In the connection conductor measurement errors due to high-frequency interference are avoided, and the connection conductor is adapted to a frequency range in which the interference occurs.

### CROSS-REFERENCE TO RELATED APPLICATION

This application claims the priority, under 35 U.S.C. § 119, of European Patent Application EP23213236.5, filed Nov. 30, 2023; the prior application is herewith incorporated by reference in its entirety.

### FIELD AND BACKGROUND OF THE INVENTION

The invention relates to a connection conductor for electrically connecting a sensor, the output side of which provides measurement signals, to an intelligent electronic device (IED) which is set up to process the measurement signals, having at least two electrically conductive conductors arranged insulated from one another, a sensor end on which is formed a conductor input for electrically connecting to an output of the sensor, and an evaluation-unit end which has a conductor output for electrically connecting to an input of the evaluation unit. The two conductors extend from the conductor input to the conductor output and are set up to transmit the measurement signals between the output of the sensor and the input of the evaluation unit.

The invention furthermore relates to an arrangement for use in the field of electrical energy supply, having a sensor for detecting an electrical variable on a conductor phase of an electrical energy supply system, an intelligent electronic device (IED) and a connection conductor extending between the sensor and the IED.

The invention moreover relates to the use of a connection conductor for transmitting measurement signals between a current sensor and an IED.

Such a connection conductor and such an arrangement are known to the person skilled in the art from practice. Connection cables are thus presently used in order to connect a sensor or sensor head, the output side of which provides analog current measurement values, to an intelligent electronic device, for example a merging unit or a protection device. In this case, the sensor head has an annular measuring part which surrounds one phase conductor of a multi-phase conductor of an electrical energy supply system. A current flowing through the phase conductor then induces a voltage in the annular measuring part, which voltage corresponds to the current flowing in the phase conductor. Once the sensor has been calibrated, the current in the phase conductor can thus be measured.

However, it has turned out that events taking place in the environment of the connection conductor, such as, for example, the switching of a circuit breaker, can generate electromagnetic interference which can adversely affect the measurement accuracy of the sensor head.

### SUMMARY OF THE INVENTION

The object of the invention is to specify a connection conductor of the type mentioned at the outset which is insensitive to external electromagnetic transient interference radiation.

With the foregoing and other objects in view there is provided, in accordance with the invention, a connection conductor for electrically connecting a sensor, an output side of the sensor providing measurement signals, to an intelligent electronic device (IED) set up to process the measurement signals. The connection conductor contains at least two electrically conductive conductor phases disposed insulated from one another, a sensor end having a conductor input for electrically connecting to an output of the sensor, and an evaluation-unit end having a conductor output for electrically connecting to an input of the intelligent electronic device being an evaluation unit. The at least two electrically conductive conductor phases extend from the conductor input to the conductor output and are set up to transmit the measurement signals between the output of the sensor and the input of the evaluation unit. The connection conductor is adapted to a frequency range in which interference occurs.

This object is achieved according to the invention starting from the above-mentioned connection conductor in that the connection conductor is adapted to a frequency range in which the interference occurs.

In the scope of the invention, it has been recognized that such transient interference events generate alternating fields—of an electromagnetic radiation—which may lie in the high-frequency range, for example in the megahertz range. Without suitable adaptation of the connection conductor to these frequencies, these transient interference fields distort the measurement results. It is therefore proposed according to the invention to adapt the connection cable to these interference frequencies. By virtue of the adaptation, the connection conductor is insensitive to the high-frequency interference fields in the sense that measurement values detected during the high-frequency interference can be reliably detected.

Tuned connection cables are indeed known to the person skilled in the art in principle from the field of high frequency. The invention, however, proposes adapting a connection conductor, which serves to transmit measurement values in the millisecond range, to the interfering frequencies in the higher frequency range. Presently, for this purpose, use is exclusively made of connection conductors which are not adapted. This is because electrical energy supply systems carry alternating currents and have alternating voltages, the fundamental oscillations of which are at 50 Hertz or 60 Hertz.

The adaptation is preferably performed using terminating resistors. Each phase conductor can thus have a terminating resistor, wherein each terminating resistor is arranged at the sensor end. This type of adaptation is inexpensive.

Advantageously, a capacitance is formed at the sensor end between the conductor phases. Since the sensor head likewise forms a capacitance or in other words a capacitor with respect to the respective phases of the conductor of the electrical energy supply system which its annular measuring part surrounds, this advantageous further development of the invention, by virtue of the additional capacitor or in other words the additional capacitance, provides a series connection of two capacitors. This series connection can also be referred to as a capacitive voltage divider. In this case, one of the conductor phases of the connection conductor is connected to a pole of the first and of the second capacitor connected downstream of the sensor. The other conductor phase of the connection conductor according to the invention is preferably grounded when the connection conductor is being used. The other conductor phase is in other words groundable or in other words able to be connected to ground potential.

Advantageously, the capacitance is arranged between the conductor input and the terminating resistors of the phase conductors. It has turned out that this electrical arrangement is most useful for making the connection conductor insensitive to high-frequency interference fields.

According to a further variant of the present invention, the phase conductors extend in a plastic sheathing such that the connection conductor is configured as a cable conductor. Cable conductors can be easily and quickly laid or connected on site.

The invention furthermore relates to an arrangement for use in the field of electrical energy supply, having a sensor for detecting an electrical variable on a phase conductor of an electrical energy supply system, an intelligent electronic device (IED) and a connection conductor, which is configured as described above, extending between the sensor and the IED. What was said above correspondingly applies to the arrangement according to the invention.

Finally, the invention also relates to the use of a connection conductor as claimed in one of the preceding claims for transmitting measurement signals between a current sensor and an IED. Tuned connection conductors or connection conductors equipped with terminating resistors are known in principle from the field of high-frequency technology. Their use between a sensor and an IED for transmitting analog measurement values has not yet been proposed, however.

According to a related further development, the IED is a protection device, a merging unit or a PMU.

Other features which are considered as characteristic for the invention are set forth in the appended claims.

Although the invention is illustrated and described herein as embodied in a connection conductor, an arrangement having a connection conductor and a use of a connection conductor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is an illustration of an exemplary embodiment of an arrangement having a connection cable according to the prior art;

FIG. 2 is an illustration of an exemplary embodiment of the connection cable according to the invention; and

FIG. 3 is an illustration of an exemplary embodiment of the arrangement according to the invention.

### DETAILED DESCRIPTION OF THE INVENTION

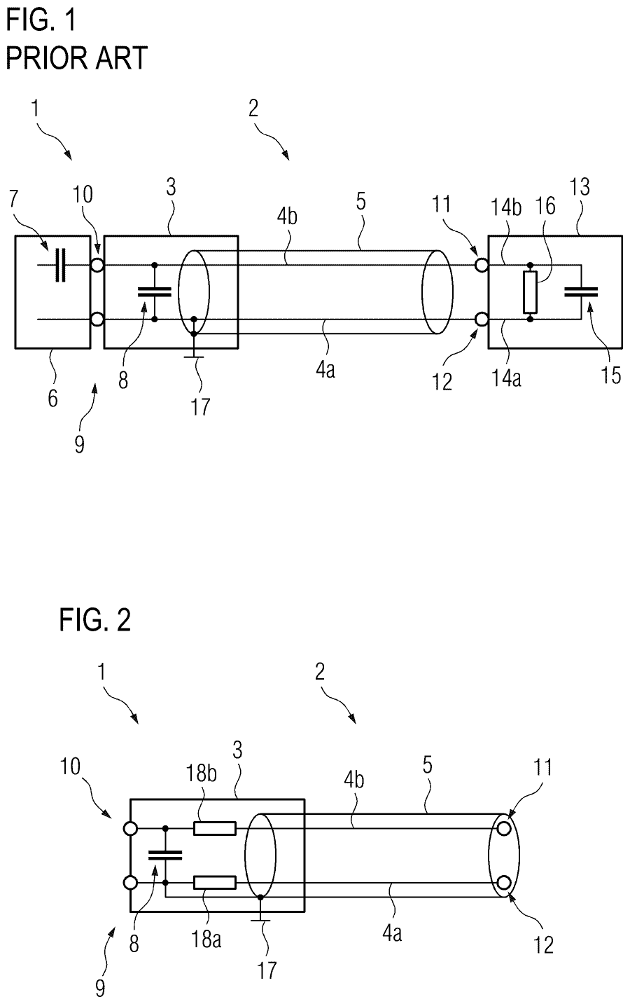

Referring now to the figures of the drawings in detail and first, particularly to FIG. 1 thereof, there is shown an exemplary embodiment of an arrangement 1 according to the prior art. The arrangement 1 has a connection conductor 2 which is configured as a connection cable 2. The connection cable 2 contains a cable plug 3 and two conductor phases 4a and 4b which are arranged electrically insulated from one another in a plastic sheathing 5. The plastic sheathing 5 surrounds the conductor phases 4a and 4b entirely. The reference sign 17 indicates that the conductor phase 4a is at ground potential. This grounding can be done via the IED.

The cable plug 3 is connected to a sensor 6 which has an annular ring conductor which is arranged in an electrical insulation, for example in a plastic housing filled with glass fibers. The sensor 6 is set up to detect currents which flow through a phase conductor of an electrical energy supply system. In this case, the ring conductor of the sensor 6 surrounds one of the phase conductors of the multi- or three-phase electrical energy supply system. Since the phase conductor carries alternating voltage, a small alternating current flows through the capacitance between the phase conductor and the metal ring conductor of the sensor. This current is proportional to the voltage present in the respective phase of the energy supply system such that, once the sensor 6 has been calibrated, the voltage can be measured.

In FIG. 1, the ring conductor of the sensor head 6 is illustrated schematically by a capacitor 7. In the cable plug 3, a further capacitor 8 can be seen arranged between the conductor phases 4a and 4b of the connection cable 2. The capacitors 7 and 8 are connected in series and form a capacitive voltage divider. By appropriately selecting the size of the capacitors 7, 8, it is thus possible to establish the desired voltage range in which the measurement voltage between the conductor phases 4a and 4b can be tapped. The capacitor 8 is soldered between the conductor phases 4a and 4b in the exemplary embodiment shown. The conductor phase 4b is connected to a pole of each of the two series-connected capacitors. That pole of the capacitor 4a which is connected to the conductor phase 4a is at ground potential, as indicated by the reference sign 17.

At a sensor end 9 of the connection conductor 2 is formed a conductor input 10 which is configured to electrically connect to an output of the sensor head 6. The conductor input 10 is formed for example by a plurality of rigid connection pins which protrude perpendicularly from a non-conductive housing plane and are able to be inserted into corresponding eyelets in the sensor head 6.

At its end facing away from the sensor 6, which is referred to as the evaluation-unit end 11 hereinbelow, the connection cable 2 forms a conductor output 12 which serves to connect to a protection device 13. The protection device 13 constitutes one of many possibilities for the configuration of an intelligent electronic device (IED).

It can be seen that the conductor phases 4a and 4b of the connection cable 2 are extended in the protection device 13. The connection conductors extending in the protection device 13 are provided with the reference signs 14a and 14b. A resistor 16, which has a size of 2 MΩ (megaohms) here, is connected between the connection conductors 14a and 14b. A capacitance in the form of a capacitor 15 (30 pF to approximately 50 pF) is connected in parallel with the resistor 16. The capacitor 15 and the parallel resistor 16 are dictated by the so-called low-power instrument transformer standard. Technically, the capacitance is physically formed by the real input connection of the IED. The value results in part from the circuit-board capacitance and semiconductor input impedance. In other words, this structure arises automatically; without this caused additional capacitance, the IED is not able to be realized. Extending the conductor phases allows the resistor at the evaluation-unit end to be operative between the conductor phases 4a and 4b.

As has already been explained further above, the disadvantage associated with the connection conductor 2 according to the prior art and the arrangement 1 according to the prior art formed thereby is that external high-frequency interference can adversely affect the measurement results. One example of such interference is the switching of a circuit breaker. In the scope of the invention, it has been recognized that the electromagnetic fields arising in this case may have a frequency in the megahertz range. Measurement errors caused by this high-frequency interference can be avoided if the cable conductor is tuned to such high-frequency interference. FIG. 2 illustrates such a connection cable 2 according to the invention.

FIG. 2 shows an exemplary embodiment of the connection conductor 2 according to the invention which is configured as a connection cable 2 as in FIG. 1. The shown connection cable 2 according to the invention has the same components as the connection cable 2 according to the prior art illustrated in FIG. 1. The explanations relating to FIG. 1 therefore correspondingly apply with regard to FIG. 2 insofar as they relate to the connection cable 2.

In contrast to the connection cable 2 according to FIG. 1, however, the connection cable 2 according to FIG. 2 has two terminating resistors 18a and 18b which are each arranged in one of the conductor phases 4a and 4b, respectively. In the example shown, the terminating resistors 18a and 18b form a resistor of 68Ω, wherein the effectiveness is also given with a 10% greater or 10% lesser value. The shown connection cable 2 is thus adapted and optimized for the dissipation of interference and its conversion into heat in the range from approximately 3 to well over 30 MHz. On account of the terminating resistors 18a and 18b, the connection cable 2 according to FIG. 2 is no longer susceptible to error in the face of high-frequency interference such that the measurement results can no longer be distorted.

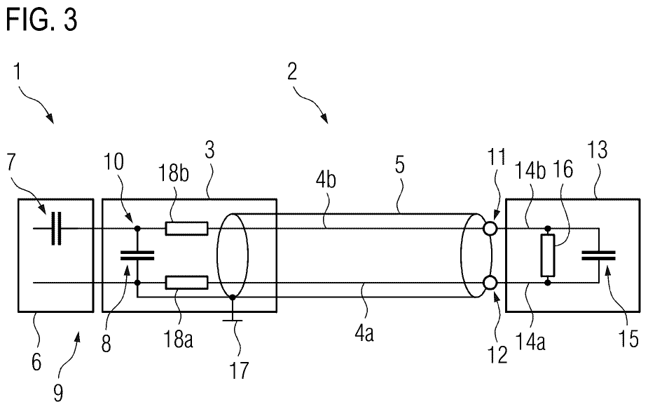

FIG. 3 shows an exemplary embodiment of the arrangement 1 according to the invention, likewise in a schematic illustration. The arrangement 1 according to FIG. 3 essentially corresponds to the illustration of the prior art according to FIG. 1 but the terminating resistors 18a and 18b are incorporated into the conductor phases 4a and 4b, respectively. In the exemplary embodiment shown in FIG. 3, the terminating resistors 1 have a resistance of 68Ω corresponding to 18a and 18b. The connection cable is thus tuned for the broadband dissipation of interference from approximately 1 to about 50 MHz. On account of this tuning, the measurement results can no longer be distorted by high-frequency interference. Apart from that, the explanations relating to FIGS. 1 and 2 correspondingly apply here.

1. A connection conductor for electrically connecting a sensor, an output side of the sensor providing measurement signals, to an intelligent electronic device (IED) set up to process the measurement signals, the connection conductor comprising:
at least two electrically conductive conductor phases disposed insulated from one another;
a sensor end having a conductor input for electrically connecting to an output of the sensor;
an evaluation-unit end having a conductor output for electrically connecting to an input of the intelligent electronic device being an evaluation unit;
said at least two electrically conductive conductor phases extending from said conductor input to said conductor output and are set up to transmit the measurement signals between the output of the sensor and the input of the evaluation unit; and
the connection conductor is adapted to a frequency range in which interference occurs.

2. The connection conductor according to claim 1, wherein each of said at least two electrically conductive phase conductors has a terminating resistor, wherein each said terminating resistor is disposed at said sensor end.

3. The connection conductor according to claim 2, further comprising a capacitance disposed at said sensor end between said at least two electrically conductive conductor phases.

4. The connection conductor according to claim 3, wherein said capacitance is disposed between said conductor input and said terminating resistors of said at least two electrically conductive conductor phases.

5. The connection conductor according to claim 1, further comprising a plastic sheathing, said at least two electrically conductive phase conductors extending in said plastic sheathing such that the connection conductor is configured as a connection cable.

6. The connection conductor according to claim 1, further comprising a resistor being operative between said at least two electrically conductive conductor phases at said evaluation-unit end.

7. A configuration for use in a field of electrical energy supply, the configuration comprising:
a sensor for detecting an electrical variable on a conductor phase of an electrical energy supply system;
an intelligent electronic device (IED); and
the connection conductor according to claim 1 extending between said sensor and said IED.

8. A method of using a connection conductor, which comprises the step of:
providing the connection conductor according to claim 1 for a fault-free transmission of the measurement signals between the sensor and the IED.

9. A method of using a connection conductor, which comprises the step of:
providing the connection conductor according to claim 1 for a fault-free transmission of the measurement signals between the sensor and the intelligent electronic device being a protection device.
